(19) United States
(12) Patent Application Publication
(10) Pub. No.: US 2006/0023779 A1
(43) Pub. Date: Feb. 2, 2006

(54) Equalizers, receivers and methods for the same

(76) Inventors: Myoung Bo Kwak, Seoul (KR); Duck Hyun Chang, Seongnam-si (KR); Ji Young Kim, Osan-si (KR); Chi Won Kim, Suwon-si (KR); Hyun Goo Kim, Seoul (KR); Jae Hyun Park, Seoul (KR); Jong Shin Shin, Seoul (KR)

Correspondence Address: HARNESS, DICKEY & PIERCE, P.L.C., P.O. BOX 8910, RESTON, VA, 20195, US

(21) Appl. No.: 11/189,879

(22) Filed: Jul. 27, 2005

(30) Foreign Application Priority Data
Jul. 29, 2004 (KR) 2004-59800

(51) Int. Cl. H03H 7/30

(52) U.S. Cl. 375/229

(57) ABSTRACT

An equalizer may include an equalizer circuit and a controller. The equalizer circuit may generate an equalized signal based on a control code and input data. The controller may generate the control code based on a transition information signal having information on a number of data transitions in each clock period between multi-phase clocks.

### PRIORITY STATEMENT

This non-provisional U.S. application claims priority under 35 U.S.C. § 119 of Korean Patent Application No. 2004-59800 filed on Jul. 29, 2004 in the Korean Intellectual Property Office (KIPO), the entire contents of which are herein incorporated by reference.

### BACKGROUND OF THE INVENTION

1. Field of the Invention

Example embodiments of the present invention relate to equalizers, receivers, and methods for the same.

2. Description of the Related Art

A frequency spectrum of a signal may be degraded when the signal passes through a transmission medium. The degradation may result in attenuation of a higher frequency component in the frequency spectrum of the signal. As a result of the degradation, narrower signal pulses may have lower peak amplitudes than wider pulses, causing recovery of bit information encoded in each pulse to be more difficult because, for example, the signal input to the receiver through the transmission media may include jitter. This jitter may make reproduction of the signal more difficult.

An equalization method may be performed on the input signal to compensate for the frequency degradation. Equalization may decrease the jitter of the input signal and restore the attenuated frequency component to its original amplitude.

A transceiver used for a higher (e.g., ultra-high) speed serial interface may operate at a data rate of about several Gbps. As the data rate increases, a jitter noise of the receiver may be a concern in a clock and data recovery (CDR). When a long cable or a printed circuit board (PCB) routing is used for the transmission media, an equalizer may be included in the receiver to reduce the inter-symbol-interference (ISI).

FIG. 1 is a block diagram showing a related art communication receiver.

Referring to FIG. 1, a received signal may be equalized by the equalizer 30 and input to a slicer 32 and an adaptation circuit 40. The slicer 32 may slice the equalized signal to transfer a sliced signal to a clock recovery circuit 34. The clock recovery circuit 34 may output an output signal and data lock signal DATA LOCK. The adaptation circuit 40 may include a coarse algorithm block 36 and a fine tune algorithm block 38. The coarse algorithm block 36 may determine a range of codes and the fine tune algorithm block 38 may select a special code from the range of codes based on the data lock signal DATA LOCK. The selected code may be applied to the equalizer 30.

A wireless receiver having a related art equalizer may determine an upper limit and a lower limit of the range of codes and may select a special code between the upper limit and the lower limit, to apply to the equalizer 30. When the data lock signal DATA LOCK does not indicate that the data is locked, the code currently used by the equalizer 30 may not be sufficient (e.g., optimal) and a different code may be selected from the range of codes. When the data lock signal DATA LOCK indicates that the data is locked, the currently used code may be used (e.g., continually used) by the equalizer 30.

### SUMMARY OF THE INVENTION

Example embodiments of the present invention may provide an equalizer digitally controlled and adapted for a receiver operating at higher speeds. The equalizer may have a smaller area in a semiconductor integrated circuit and/or reduced power consumption.

Example embodiments of the present invention may also provide an equalization method, which may be digitally controlled and adapted for a receiver operating at higher speeds.

Example embodiments of the present invention may also provide a receiver operating at higher speeds.

In an example embodiment of the present invention, an equalizer may include an equalizer circuit and a controller. The equalizer circuit may be configured to generate an equalized signal based on a control code and input data and the controller may be configured to generate the control code based on a transition information signal indicative of a number of data transitions in each clock period between multi-phase clocks.

In another example embodiment of the present invention, a receiver may include an equalizer, a sampler and a recovery circuit. The equalizer may be configured to generate an equalized signal pair based on a transition information signal. The sampler may be configured to sample the equalized signal pair to output a sampled signal based on a clock signal having multiple phases. The recovery circuit may be configured to generate the transition information signal indicative of a number of data transitions in each clock period between multi-phase clocks.

In another example embodiments of the present invention, a method may include initializing an equalizer control code, counting and recording a number of clock periods in which data transitions occur between the multi-phase clocks, deciding whether the equalizer control code has reached an upper limit, increasing the equalizer control code by a unit value when the equalizer control code has not reach the upper limit, and setting an optimum control code when the control code has reached the upper limit and the number of the clock periods in which the data transition occurs is the smallest.

In example embodiments of the present invention, the input data and the equalized signal may each include a signal pair.

In example embodiments of the present invention, the equalizer circuit may further include a transistor pair, at least one of at least one resistor and at least one capacitor, and an impedance adjustment circuit. The transistor pair may have a gate to which the input data may be applied. The at least one resistor and/or at least one capacitor may be coupled between the sources of the transistor pair, and the impedance adjustment circuit may be coupled to the capacitor.

In example embodiments of the present invention, a capacitor may be coupled between the sources of the transistor pair, the impedance adjustment circuit may be coupled to the capacitor and the impedance adjustment circuit may include resistors and switches. The resistors may have a first terminal coupled to a first terminal of the capacitor, and the switches may be controllable by the control code and coupled between a second terminal of each of the control resistors and a second terminal of the capacitor.

In example embodiments of the present invention, each of the switches may include a transistor having a gate that receives one bit of the control code.

In example embodiments of the present invention, the control resistors may have equal resistance and/or a weight may be applied to each of the control resistors.

In example embodiments of the present invention, a resistor may have a first terminal coupled to a source of a first transistor of the transistor pair, a capacitor may be coupled between a second terminal of the resistor and a source of a second transistor of the transistor pair, the impedance adjustment circuit may be coupled in parallel with the capacitor, and the impedance adjustment circuit may include resistors and switches. The resistors may have a first terminal coupled to a first terminal of the capacitor, and the switches may be controllable by the control code and coupled between a second terminal of each of the resistors and a second terminal of the capacitor.

In example embodiments of the present invention, a resistor may be coupled between sources of the transistor pair, the impedance adjustment circuit may be coupled to the resistor, and the impedance adjustment circuit may include capacitors and switches. The capacitors may each have a first terminal coupled to a first terminal of the resistor, and the switches may be controllable by the control code and coupled between a second terminal of each of the control capacitors and a second terminal of the resistor.

In example embodiments of the present invention, a weight may be applied to each of the capacitors.

In example embodiments of the present invention, a first terminal of a first resistor may be coupled to a source of a first transistor of the transistor pair, a second resistor may be coupled between a second terminal of the first resistor and a source of a second transistor of the transistor pair, the impedance adjustment circuit may be coupled to the second resistor, and the impedance adjustment circuit may include capacitors and switches. The capacitors may have a first terminal coupled to a first terminal of the second resistor, and the switches may be controllable by the control code and coupled between a second terminal of each of the capacitors and a second terminal of the resistor.

In example embodiments of the present invention, the controller may repeatedly count a number of the clock periods in which the data transition occurs and may vary the control code based-on the transition information signal.

In example embodiments of the present invention, the controller may set a control code (e.g., an optimum control code) when the control code reaches an upper limit and a number of the clock periods in which the data transition occurs is small (e.g., the smallest).

### BRIEF DESCRIPTION OF THE DRAWINGS

Example embodiments of the present invention will be apparent from the description of example embodiments of the present invention, as illustrated in the drawings. However, the drawings may not be necessarily to scale, emphasis instead being placed upon illustrating the principles of the present invention. Like reference characters refer to like elements throughout the drawings.

FIG. 1 is a block diagram showing a related art communication receiver;

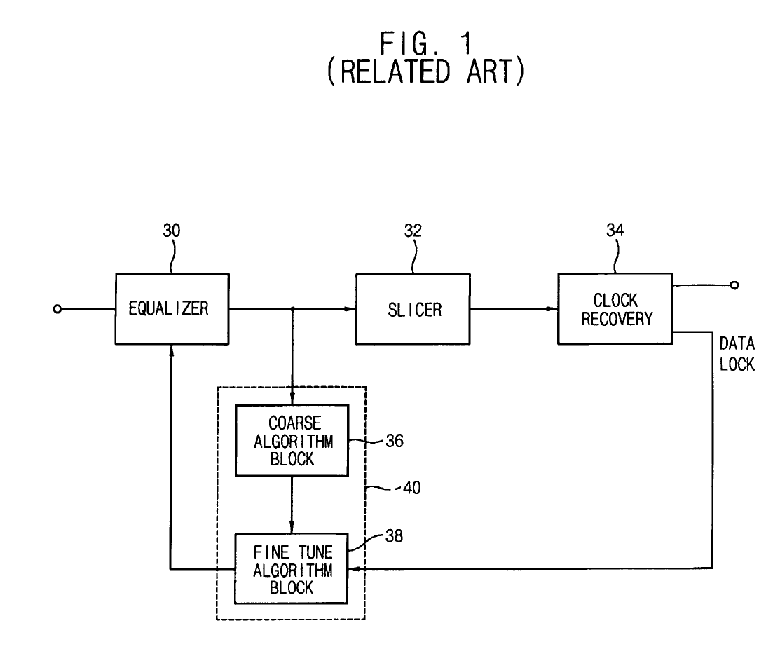

FIG. 2 is a schematic view illustrating a relationship between a serial input data and a sampling clock;

FIG. 3 is a block diagram showing a communication receiver having an equalizer according to an example embodiment of the present invention;

FIG. 4 is a circuit diagram showing an equalizer in the communication receiver of FIG. 3, according to an example embodiment of the present invention;

FIG. 5 is a flow chart illustrating an equalization method, according to an example embodiment of the present invention; and

FIG. 6 is a circuit diagram showing an equalizer in the communication receiver of FIG. 3, according to another example embodiment of the present invention.

### DESCRIPTION OF EXAMPLE EMBODIMENTS OF THE PRESENT INVENTION

Example embodiments of the present invention are disclosed herein for example purposes. However, specific structural and functional details disclosed in example embodiments of the present invention are representative for purposes of describing example embodiments of the present invention.

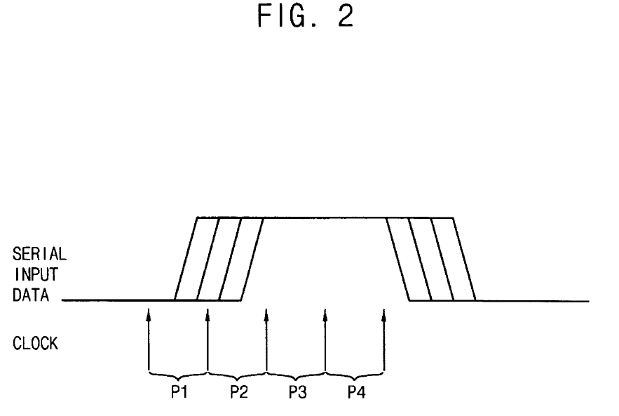

FIG. 2 is a schematic view illustrating the relationship between serial input data and a sampling clock. Referring to FIG. 2, for clock intervals P1 to P4 between multi-phase clock signals CLOCK, the number of transitions of serial input data may be, for example, 2 for the interval P1, 2 for the interval P2, 0 for the interval P3, and 0 for the interval P4.

According to an example embodiment of the present invention, the number of clock periods in which the transition of the input data is generated may be counted while adjusting an equalizer control code. The equalizer control code may be set as control data for the equalizer, for example, when the number of the clock periods in which the transition of the input data occurs is reduced (e.g., at a minimum).

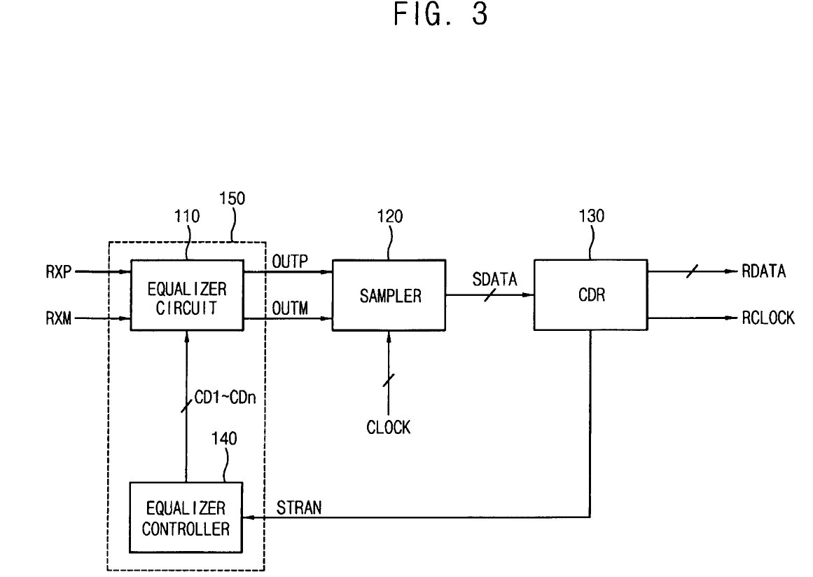

FIG. 3 is a block diagram showing a receiver including an equalizer, according to an example embodiment of the present invention. Referring to FIG. 3, the receiver may include an equalizer 150, a sampler 120, and a recovery circuit (e.g., clock/data recovery circuit) 130. The equalizer 150 may further include an equalizer circuit 110 and a controller (e.g., equalizer controller) 140. The equalizer circuit 110 may generate an equalized signal pair OUTP and OUTM based on an input signal pair RXP and RXM and an n-bit control code CD1 to CDn. The sampler 120 may sample the equalized signal pair OUTP and OUTM to output a sampled signal SDATA based on the clock signal CLOCK having, for example, multiple phases. The recovery circuit 130 may generate recovered data RDATA and recovered clock signals RCLOCK based on the sampled signal SDATA. The recovery circuit 130 may generate a transition information signal STRAN having information regarding the location and number of transitions of the input data between multi-phase clocks. The equalizer controller 140 may generate the control code CD1 to CDn based on the transition information signal STRAN.

FlG. 4 is a circuit diagram showing the equalizer circuit 110 in the receiver of FIG. 3, according to an example embodiment of the present invention.

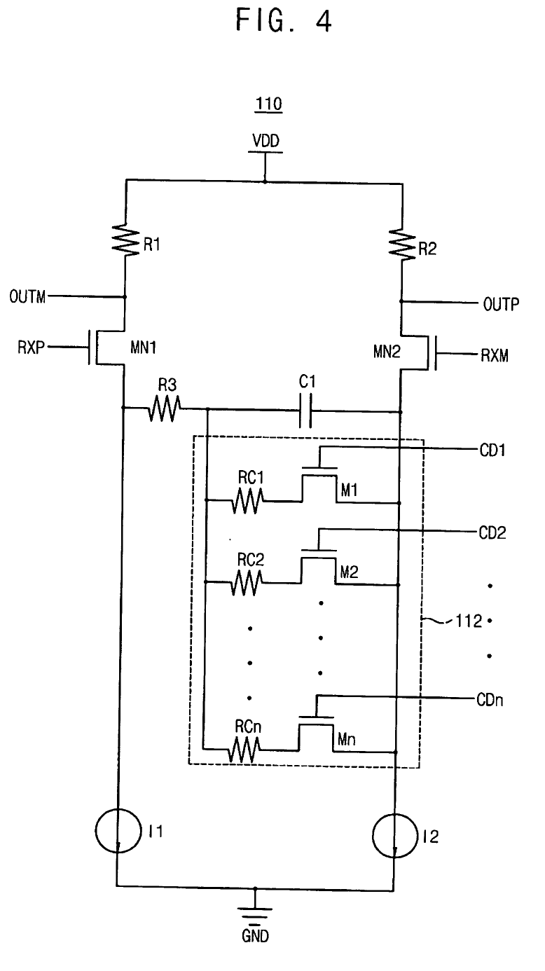

Referring to FIG. 4, the equalizer circuit 110 may receive the input signal pair RXP and RXM and may output the output signal pair OUTP and OUTM. The equalizer circuit 110 may include resistors R1 to R3, a capacitor C1, an impedance adjustment circuit 112, transistors (e.g., NMOS transistors) MN1 and MN2, and current sources I1 and I2. The input signal pair RXP and RXM may be applied to the gates of the transistors MN1 and MN2, respectively. The resistor R1 may be coupled between the drain of the transistor MN1 and a supply voltage VDD. The resistor R2 may be coupled between the drain of the transistor MN2 and the supply voltage VDD. The resistor R3 may have a first end coupled to the source of the transistor MN1 and a second end coupled to the capacitor C1. The capacitor C1 may be coupled between the second end of the resistor R3 and the source of the transistor MN2.

The current source I1 may be coupled between the source of the transistor MN1 and a ground GND. The current source I2 may be coupled between the source of the transistor MN2 and the ground GND. The impedance adjustment circuit 112 may be coupled, for example, in parallel to the capacitor C1. The impedance adjustment circuit 112 may include a plurality of resistors RC1 to RCn and a plurality of transistors M1 to Mn, which may be coupled (e.g., serially coupled) to the resistors RC1 to RCn, respectively. One of the control codes CD1 to CDn may be coupled to each gate of the transistors M1 to Mn. In FIG. 4, the resistor R3 need not be included for some applications.

Hereinafter, the operation of the equalizer circuit 110, according to an example embodiment of the present invention, will be described referring to FIG. 3 and FIG. 4.

The equalizer circuit 10 may equalize the input signal pair RXP and RXM. This equalization may decrease the jitter included in the input signal pair RXP and the frequency component attenuated by a transmission media may be recovered. For example, a frequency response of the equalizer circuit 110 may be varied according to the control codes CD1 to CDn, and the amount of the jitter included in the output signal pair OUTP and OUTM of the equalizer circuit 110 may be varied.

The sampler 120 may sample the equalized signal pair OUTP and OUTM based on the multi-phase clock signal CLOCK. The recovery circuit (e.g., clock/data recovery circuit) 130 may generate the recovered data RDATA and the recovered clock signal RCLOCK based on the sampled signal SDATA. A transition information signal STRAN, another output signal of the recovery circuit 130, may have information on a location and number of transitions of the input data that may occur between multi-phase clocks. The equalizer controller 140 may generate the control codes CD1 to CDn based on the transition information signal STRAN.

The equalizer controller 140 may increase the control codes CD1 to CDn, for example, by one at each cycle to apply the control codes CD1 to CDn to the equalizer circuit 110. As shown in FIG. 4, the control codes CD1 to CDn may be applied bit by bit to each gate of the transistors M1 to Mn of the impedance adjustment circuit 112. The resistors RC1 to RCn of the impedance adjustment circuit 112 may have the same, or substantially the same, resistance. Alternatively, the resistors RC1 to RCn may have different resistances from one another, for example, by applying different weights to the resistors RC1 to RCn.

For example, when the control codes CD1 to CDn have four-bit data, respectively, and the resistors RC1 to RC4 are weighted, the control code at a first cycle may have a binary value ‘0001’, the control code at a second cycle may have a binary value ‘0010’ and the control code at a third cycle may have a binary value ‘0011’. When the control codes CD1 to CDn have four-bit data and the resistors RC1 to RC4 have the same, or substantially the same, resistance, the control code at the first cycle may have a binary value ‘0001’, the control code at the second cycle may have a binary value ‘0011’ and the control code at the third cycle may have a binary value ‘0111’.

When each bit of the control codes CD1 to CDn has a logic value of “1”, the transistors M1, M2, and Mn of the impedance adjustment circuit 112 may be turned on and the resistors RC1, RC2, and RCn may be coupled (e.g., serially coupled) to the transistors M1, M2, and Mn may be coupled (e.g., coupled in parallel) to the capacitor C1. When each bit of the control codes CD1 to CDn has logic value of “0”, the transistors M1, M2, and Mn may be turned off, and the resistors RC1, RC2, and RCn may be coupled (e.g., serially coupled) to the transistors M1, M2, and Mn may be floated.

For example, when each bit of the control codes CD1 to CDn has a logic value of “1”, the resistance of the resistor coupled (e.g., in parallel) to the capacitor C1 may increase. When each bit of the control codes CD1 to CDn has a logic value of “0”, the resistance of the resistor coupled (e.g., coupled in parallel) to the capacitor C1 may decrease. Depending on the impedance between the sources of the transistors MN1 and MN2, the frequency characteristic of the output signal pair OUTP and OUTM may vary.

The equalizer controller 140 may repeatedly count the number of clock periods in which the transition of the input data may be generated between the multi-phase clocks CLOCK and may vary the control code CD1 to CDn based on the transition information signal STRAN. When the control code CD1 to CDn reaches an upper level (e.g., an upper limit or maximum) and the number of clock periods in which the number of the transition of the input data is smaller (e.g., smallest or minimum), the equalizer controller 140 may set a suitable (e.g., an optimum) control code.

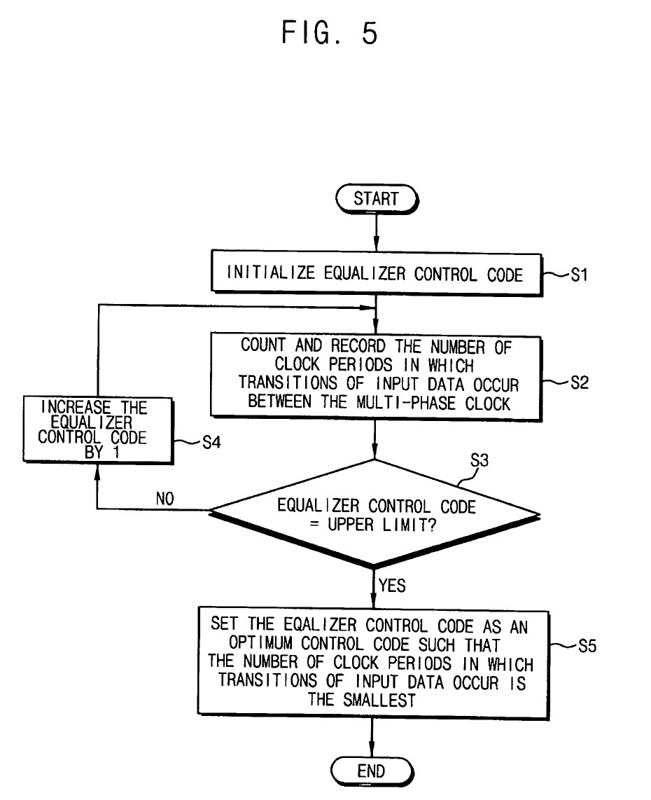

FIG. 5 is a flow chart illustrating a method (e.g., an adaptive equalization method), according to an example embodiment of the present invention. Referring to FIG. 5, the method, according to an example embodiment of the present invention, may include initializing an equalizer control code at S1, counting and recording a number of clock periods in which transitions of input data occur at S2, deciding whether the equalizer control code reaches an upper level at S3, increasing the equalizer control code by one, for example, when the equalizer control code does not reach the upper level at S4 and setting a suitable control code (e.g., an optimum control code), for example, when the control code reaches the upper level and the number of clock periods on which the transition of the input data is small (e.g., smallest) at S5.

A method according to example embodiments of the present invention may repeatedly count the number of clock periods in which the input data transitions between the multi-phase clocks CLOCK and control code CD1 to CDn varies based on the transition information signal STRAN. When the control code reaches the upper level and the number of clock periods on which the transition of the input data is smaller (e.g., smallest), the control code may be set at a suitable (e.g., an optimum) control code.

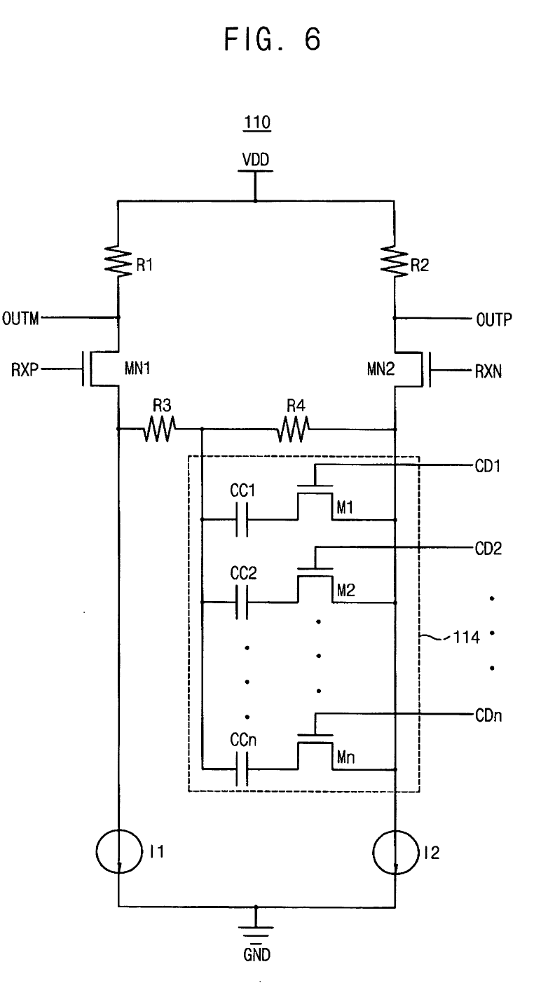

FIG. 6 is a circuit diagram showing an equalizer circuit 110 in the communication receiver of FIG. 3, according to another example embodiment of the present invention. The equalizer circuit of FIG. 6 may be similar, or substantially similar, to the equalizer circuit of FIG. 4; however, the impedance adjustment circuit 114 may include capacitors CC1, CC2, . . . , CCn instead of resistors.

Referring to FIG. 6, the equalizer circuit 10 may receive the input signal pair RXP and RXM and may output the output signal pair OUTP and OUTM. The equalizer circuit 110 may include the resistors R1 to R4, the impedance adjustment circuit 114, the transistors MN1 and MN2, and the current sources I1 and I2.

The input signal pair RXP and RXM may be applied to the gates of the transistors MN1 and MN2, respectively. The resistor R1 may be coupled between the drain of the transistor MN1 and the supply voltage VDD and the resistor R2 may be coupled between the drain of the NMOS transistor MN2 and the supply voltage VDD. The resistor R3 may have a first end coupled to the source of the transistor MN1 and a second end coupled to the resistor R4. The resistor R4 may be coupled between the second end of the resistor R3 and the source of the NMOS transistor MN2.

The current source I1 may be coupled between the source of the transistor MN1 and the ground GND and the current source I2 may be coupled between the source of the transistor MN2 and the ground GND. The impedance adjustment circuit 114 may be coupled (e.g., coupled in parallel) to the resistor R4. The impedance adjustment circuit 114 may include a plurality of capacitors CC1 to CCn and a plurality of transistors M1 to Mn coupled (e.g., serially coupled) to the capacitors CC1 to CCn, respectively. One of the control codes CD1 to CDn may be coupled to each gate of the transistors M1 to Mn. In FIG. 6, the resistor R3 need not be included for some applications.

The equalizer circuit of FIG. 6 may adjust the frequency response of the equalizer, for example, by varying the capacitance of the impedance adjustment circuit 114. The operation of the equalizer circuit 110 of FIG. 6 may be similar, or substantially similar, to the equalizer circuit of FIG. 4 and thus the description will be omitted.

According to example embodiments of the present invention, the adaptive equalizer may be digitally controlled, adapted to the receiver operating at higher speeds.

The equalizer, according to example embodiments of the present invention, may decrease jitter included in the input data more easily, may have a smaller area in the semiconductor integrated circuit, and/or may reduce power consumption.

Although example embodiments of the present invention have been described with regard to NMOS transistors, it will be understood that any suitable transistor may be used (e.g., PMOS transistors, etc.).

Although example embodiments of the present invention have been discussed with respect to logic signals “1” and/or “0”, it will be understood that any suitable logic signals may be used (e.g., logic high, ‘H’, low, ‘L’, etc.).

Although example embodiments of the present invention have been discussed with regard to four bit control codes, it will be understood that any suitable length control code may be used (e.g., two bit, four bit, eight bit, etc.).

Although aspects of example embodiments of the present invention have been discussed with regard to specific figures, it will be understood that various components of example embodiments of the present invention may be interchangeable. For example, in the example embodiment of the present invention as shown in FIG. 4, the capacitor C1 and the resistor R3 may both be capacitors or resistors.

While example embodiments of the present invention have been described herein, it should be understood that various changes, substitutions and alterations can be made herein without departing from the scope of the present invention as defined by appended claims.

What is claimed is:

1. An equalizer, comprising:
an equalizer circuit configured to generate an equalized signal based on a control code and input data; and
a controller configured to generate the control code based on a transition information signal indicative of a number of data transitions in each clock period between multi-phase clocks.

2. The equalizer of claim 1, wherein the input data and the equalized signal each include a signal pair.

3. The equalizer of claim 1, wherein the equalizer circuit further includes,
a transistor pair having a gate to which the input data is applied,
at least one of at least one resistor and at least one capacitor coupled between the sources of the transistor pair, and
an impedance adjustment circuit coupled to the capacitor.

4. The equalizer of claim 3, wherein a capacitor is coupled between the sources of the transistor pair, the impedance adjustment circuit coupled to the capacitor and the impedance adjustment circuit includes,
control resistors having a first terminal coupled to a first terminal of the capacitor, and
switches, controllable by the control code, and coupled between a second terminal of each of the control resistors and a second terminal of the capacitor.

5. The equalizer of claim 4, wherein each of the switches includes a transistor having a gate that receives one bit of the control code.

6. The equalizer of claim 5, wherein the transistors are MOS transistors

7. The equalizer of claim 4, wherein the control resistors have equal resistance.

8. The equalizer of claim 4, wherein a weight is applied to each of the control resistors.

9. The equalizer of claim 3, wherein a resistor has a first terminal coupled to a source of a first transistor of the transistor pair, a capacitor is coupled between a second terminal of the resistor and a source of a second transistor of the transistor pair, the impedance adjustment circuit is coupled in parallel with the capacitor, and the impedance adjustment circuit includes,
control resistors having a first terminal coupled to a first terminal of the capacitor, and
switches, controllable by the control code, and coupled between a second terminal of each of the resistors and a second terminal of the capacitor.

10. The equalizer of claim 9, wherein each of the switches includes a transistor having a gate for receiving one bit of the control code.

11. The equalizer of claim 9, wherein the control resistors have equal resistance.

12. The equalizer of claim 9, wherein a weight is applied to each of the control resistors.

13. The equalizer of claim 3, wherein a resistor is coupled between sources of the transistor pair, the impedance adjustment circuit is coupled to the resistor, and the impedance adjustment circuit includes,
control capacitors each of which has a first terminal coupled to a first terminal of the resistor, and
switches, controllable by the control code, and coupled between a second terminal of each of the control capacitors and a second terminal of the resistor.

14. The equalizer of claim 13, wherein each of the switches includes a transistor having a gate for receiving one bit of the control code.

15. The equalizer of claim 13, wherein the control capacitors have equal capacitance.

16. The equalizer of claim 13, wherein a weight is applied to each of the control capacitors.

17. The equalizer of claim 3, wherein a first terminal of a first resistor is coupled to a source of a first transistor of the transistor pair, a second resistor is coupled between a second terminal of the first resistor and a source of a second transistor of the transistor pair, the impedance adjustment circuit is coupled to the second resistor, and the impedance adjustment circuit includes,
control capacitors having a first terminal coupled to a first terminal of the second resistor, and
switches, controllable by the control code, and coupled between a second terminal of each of the control capacitors and a second terminal of the resistor.

18. The equalizer of claim 17, wherein each of the switches includes a transistor having a gate for receiving one bit of the control code.

19. The equalizer of claim 1, wherein the controller repeatedly counts a number of the clock periods in which the data transition occurs and varies the control code based on the transition information signal.

20. The adaptive equalizer of claim 1, wherein the controller sets an optimum control code when the control code reaches an upper limit and a number of the clock periods in which the data transition occurs is the smallest.

21. A receiver, comprising:
an equalizer configured to generate an equalized signal pair based on a transition information signal;
a sampler configured to sample the equalized signal pair to output a sampled signal based on a clock signal having multiple phases; and
a recovery circuit configured to generate the transition information signal indicative of a number of data transitions in each clock period between multi-phase clocks.

22. The receiver of claim 21, wherein the equalizer includes,
an equalizer circuit configured to generate the equalized signal based on a control code and the input data, and
a controller configured to generate the control code based on the transition information signal.

23. The receiver of claim 22, wherein the input data and the equalized signal each include a signal pair.

24. The receiver of claim 22, wherein the equalizer circuit further includes,
a transistor pair having a gate to which the input data is applied,
at least one of at least one resistor and at least one capacitor coupled between the sources of the transistor pair, and
an impedance adjustment circuit coupled to the capacitor.

25. The receiver of claim 24, wherein a capacitor is coupled between the sources of the differential transistor pair, the impedance adjustment circuit is coupled parallel with the capacitor, and the impedance adjustment circuit includes,
control resistors each of which has a first terminal coupled to a first terminal of the capacitor, and
switches coupled between a second terminal of each of the resistors and a second terminal of the capacitor, configured to be controlled by the control code.

26. The receiver of claim 25, wherein each of the switches includes a transistor having a gate for receiving one bit of the control code.

27. The receiver of claim 24, wherein a resistor has a first terminal coupled to a source of a first transistor of the transistor pair, a capacitor is coupled between a second terminal of the resistor and a source of a second transistor of the transistor pair, the impedance adjustment circuit is coupled in parallel with the capacitor, and the impedance adjustment circuit includes,
control resistors having a first terminal coupled to a first terminal of the capacitor, and
switches, controllable by the control code, and coupled between a second terminal of each of the resistors and a second terminal of the capacitor.

28. The receiver of claim 24, wherein a resistor is coupled between sources of the transistor pair, the impedance adjustment circuit is coupled to the resistor, and the impedance adjustment circuit includes,
control capacitors each of which has a first terminal coupled to a first terminal of the resistor, and
switches, controllable by the control code, and coupled between a second terminal of each of the control capacitors and a second terminal of the resistor.

29. The receiver of claim 22, wherein the controller repeatedly counts a number of the clock periods in which the data transition occurs and varies the control code based on the transition information signal.

30. The receiver of claim 22, wherein the controller sets an optimum control code when the control code reaches an upper limit and a number of the clock periods in which the data transition occurs is the smallest.

31. A method, comprising:
initializing an equalizer control code;
counting and recording a number of clock periods in which data transitions occur between the multi-phase clocks;
deciding whether the equalizer control code has reached an upper limit;
increasing the equalizer control code by a unit value when the equalizer control code has not reach the upper limit; and
setting an optimum control code when the control code has reached the upper limit and the number of the clock periods in which the data transition occurs is the smallest.

32. An equalizer adapted to perform the method of claim 31.

33. A receiver including the equalizer of claim 32.
